(19) United States
(12) Patent Application Publication
(10) Pub. No.: US 2023/0238217 A1
(43) Pub. Date: Jul. 27, 2023

(54) PLASMA PROCESSING APPARATUS

(71) Applicant: Tokyo Electron Limited, Tokyo (JP)

(72) Inventors: Koji KOTANI, Osaka (JP); Eiki KAMATA, Nirasaki City (JP); Taro IKEDA, Nirasaki City (JP)

(21) Appl. No.: 18/156,618

(22) Filed: Jan. 19, 2023

(30) Foreign Application Priority Data
Jan. 24, 2022 (JP) 2022-008793

(51) Int. Cl. H01J 37/32

(52) U.S. Cl. CPC H01J 37/32238; H01J 37/3222

(57) ABSTRACT

A plasma processing apparatus includes: a processing container; a ceiling plate that constitutes a ceiling wall of the processing container, is formed of a first dielectric, and has an opening formed in the first dielectric; at least one transmissive window disposed in the opening and formed of a second dielectric having a second permittivity greater than a first permittivity of the first dielectric; and at least one electromagnetic wave supplier configured to supply electromagnetic waves toward the at least one transmissive window.

### CROSS-REFERENCE TO RELATED APPLICATION

This application is based upon and claims the benefit of priority from Japanese Patent Application No. 2022-008793, filed on Jan. 24, 2022, the entire contents of which are incorporated herein by reference.

### TECHNICAL FIELD

The present disclosure relates to a plasma processing apparatus.

### BACKGROUND

Patent Document 1 discloses a plasma processing apparatus including an antenna that emits microwaves into a processing chamber and a dielectric member that transmits therethrough the microwaves emitted from the antenna to form surface waves. In addition, Patent Document 1 proposes that a length of a closed circuit, through which a surface current and a displacement current flow, is set to nλ₀±δ (where n is a positive integer, λ₀ is a wavelength of microwaves, and δ is a fine adjustment component (including zero)). Thus, since the surface current may be increased and a plasma absorption efficiency is increased, a rate of increase in electron density caused by an increased input power may rise.

Patent Document 2 discloses a plasma processing apparatus including a processing chamber, a dielectric window having a flat plate shape, an induction coil, a plate electrode, a radio frequency power supply, a gas supply device, and a sample table on which a sample is placed. A dielectric of a high permittivity material is provided between the dielectric window and a processing gas supply plate, so that a generated electric field is absorbed by the dielectric of the high permittivity material. Therefore, an effective voltage value is reduced, and the distribution of electric field becomes non-uniform. By forming a notch in a Faraday shield on the top of the dielectric window in order to prevent the occurrence above, the electric field immediately below the notch may be weakened, which makes the distribution of electric field uniform.

### PRIOR ART DOCUMENTS

### Patent Documents

Patent Document 1: Japanese Laid-Open Patent Publication No. 2013-175430
Patent Document 2: Japanese Laid-Open Patent Publication No. 2013-254723

### SUMMARY

According to an embodiment of the present disclosure, a plasma processing apparatus includes: a processing container; a ceiling plate that constitutes a ceiling wall of the processing container, is formed of a first dielectric, and has an opening formed in the first dielectric; at least one transmissive window disposed in the opening and formed of a second dielectric having a second permittivity greater than a first permittivity of the first dielectric; and at least one electromagnetic wave supplier configured to supply electromagnetic waves toward the at least one transmissive window.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view illustrating an example of a plasma processing apparatus according to an embodiment.

FIG. 2 is a diagram illustrating an example of a microwave plasma source used in the plasma processing apparatus of FIG. 1.

FIG. 3 is a diagram illustrating an example of a lower surface of a ceiling plate of the plasma processing apparatus of FIG. 1.

FIG. 4 is a diagram schematically illustrating an arrangement of transmissive windows and a local plasma generation according to an embodiment.

FIGS. 5A and 5B are diagrams illustrating configurations around ceiling plates according to a reference example and an embodiment.

FIGS. 6A and 6B are diagrams illustrating a distribution of electric field intensity in the ceiling plates according to the reference example and the embodiment.

FIGS. 7A and 7B are diagrams illustrating a radius of the transmissive window and a microwave propagation preventing effect according to an embodiment.

FIGS. 8A and 8B are diagrams illustrating an example of the radius of the transmissive window and an electric field intensity at an outer edge of the ceiling plate according to an embodiment.

FIG. 9 is a diagram illustrating an example of a permittivity of the transmissive window and the electric field intensity at the outer edge of the ceiling plate according to an embodiment.

### DETAILED DESCRIPTION

Hereinafter, embodiments for carrying out the present disclosure will be described with reference to the drawings. In each drawing, the same components will be denoted by the same reference numerals, and redundant explanations thereof may be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In this specification, in the directions of parallel, right angle, orthogonal, horizontal, vertical, up/down, left/right, and the like, a deviation that does not impair the effect of an embodiment is allowed. The shape of a corner is not limited to a right angle but may be rounded in an arch shape. The terms parallel, right-angled, orthogonal, horizontal, vertical, circular, cylindrical, disk, and coincident may include approximately parallel, approximately right-angled, approximately orthogonal, approximately horizontal, approximately vertical, approximately circular, approximately cylindrical, approximately disk, and approximately coincident.

### [Plasma Processing Apparatus]

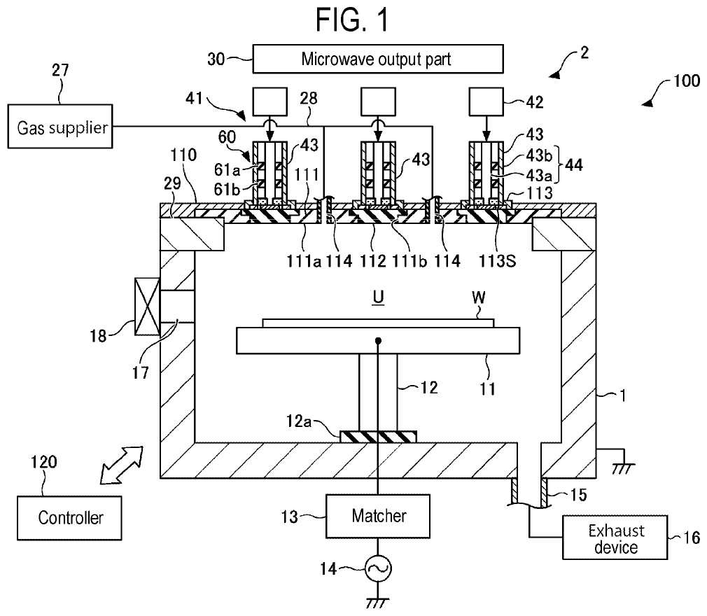

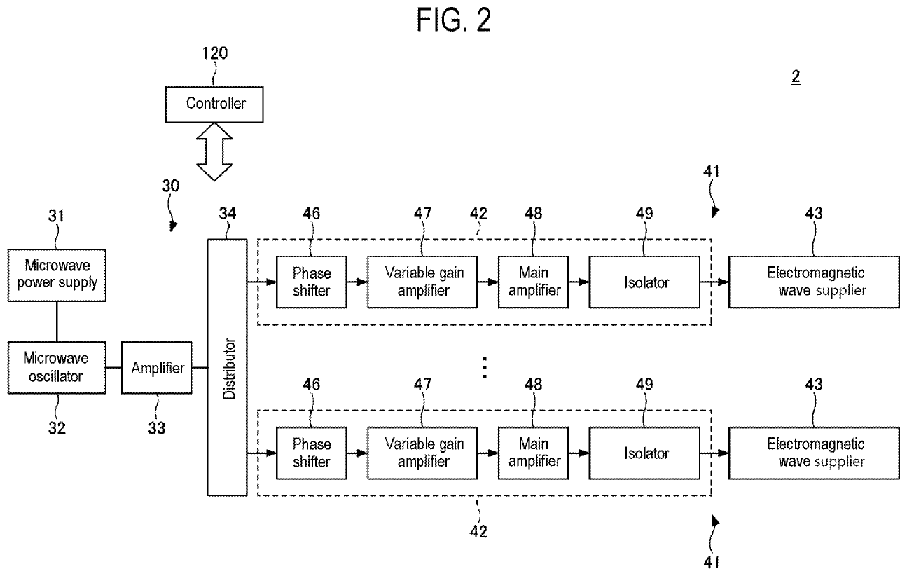

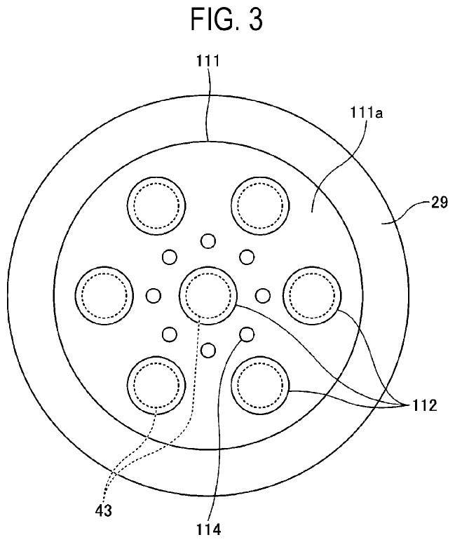

First, a configuration example of a plasma processing apparatus 100 according to an embodiment will be described with reference to FIGS. 1 to 3. FIG. 1 is a cross-sectional view illustrating an example of the plasma processing apparatus 100 according to an embodiment. FIG. 2 is a diagram illustrating an example of a microwave plasma source 2 used in the plasma processing apparatus 100 of FIG. 1. FIG. 3 is a diagram illustrating an example of a lower surface of a ceiling plate 111 of the plasma processing apparatus 100 of FIG. 1.

The plasma processing apparatus 100 performs, for example, a plasma processing, such as an etching processing or a film forming processing, on a substrate W used as example of a wafer. The plasma processing apparatus 100 includes a processing container 1 that is configured in an airtight manner and is made of a metal such as aluminum or stainless steel, and the microwave plasma source 2 that is configured to form microwave plasma inside the processing container 1. The processing container 1 has a cylindrical shape and is grounded. The top of the processing container 1 forms an opening, and a support ring 29 is provided to surround the opening. The microwave plasma source 2 is provided to face an interior of the processing container 1 from the opening.

A stage 11 for horizontally supporting the substrate W is provided inside the processing container 1 so as to be supported by a cylindrical support member 12 that is erected at the center of the bottom of the processing container 1 via an insulating member 12a interposed between the support member 12 and the bottom of the processing container 1. An example of a material constituting the stage 11 and the support member 12 may include aluminum whose surface is alumite-treated (anodized).

Further, although not illustrated, the stage 11 is provided with an electrostatic chuck for electrostatically attracting the substrate W, a temperature control mechanism, a heat-transfer-gas flow path for supplying a heat transfer gas to a back surface of the substrate W, lifting pins configured to move up and down so as to transfer the substrate W, and the like. Furthermore, a radio-frequency bias power supply 14 is electrically connected to the stage 11 via a matcher 13. When radio frequency power is supplied from the radio-frequency bias power supply 14 to the stage 11, ions in plasma are drawn to the side of the substrate W.

An exhaust pipe 15 is connected to the bottom of the processing container 1, and an exhaust device 16 including a vacuum pump is connected to the exhaust pipe 15. The interior of the processing container 1 is exhausted by operating the exhaust device 16, so that the interior of the processing container 1 may be rapidly reduced in pressure to a predetermined degree of vacuum. Further, a sidewall of the processing container 1 is provided with a loading/unloading port 17 for loading and unloading the substrate W therethrough, and a gate valve 18 that opens and closes the loading/unloading port 17.

The ceiling plate 111 closes the opening formed in the top of the processing container 1 while being supported by the support ring 29 at the top of the processing container 1. As a result, a ceiling wall of the processing container 1 is constituted with the ceiling plate 111, and the processing container 1 and the ceiling plate 111 define a plasma generation space U. The ceiling plate 111 is formed of a dielectric with high plasma resistance. This makes it possible to avoid damage to the ceiling plate 111 due to microwaves emitted from the microwave plasma source 2 and, as a result, may prevent generation of particles or contamination.

The ceiling plate 111 has a disk shape (circular flat plate shape) and is formed of a dielectric (hereinafter also referred to as “first dielectric”). The first dielectric includes a plurality of openings 111b. A transmissive window 112 is formed of a dielectric (hereinafter also referred to as “second dielectric”) having a permittivity greater than that of the first dielectric, and is fitted into each opening 111b.

A thickness of the second dielectric forming the transmissive window 112 is the same as that of the first dielectric forming the ceiling plate 111. That is, a surface of the second dielectric exposed to the plasma generation space U (that is, a lower surface 111a) is flush with a surface of the first dielectric that is adjacent to the second dielectric and is exposed to the plasma generation space U. However, the entire surface of the first dielectric exposed to the plasma generation space U may not be a flat surface. For example, a recess or the like may be formed in a surface of the first dielectric other than the surface adjacent to the second dielectric. Further, a surface of the second dielectric opposite to the surface exposed to the plasma generation space U is flush with a surface of the first dielectric opposite to the surface that is adjacent to the second dielectric and is exposed to the plasma generation space U.

The permittivity of the second dielectric is greater than that of the first dielectric. Accordingly, the transmissive window 112 functions to confine the electromagnetic field of microwaves inside the second dielectric when transmitting the microwaves therethrough. For example, the first dielectric may be alumina (Al₂O₃) having a permittivity of about 9.6, or quartz having a permittivity of about 3.7 to 4, and the second dielectric may be a high permittivity material such as zirconia having a permittivity of 30. Ranges of a radius and an available permittivity of the second dielectric will be described later.

The microwave plasma source 2 is disposed on the top of the ceiling plate 111. In detail, an electromagnetic wave supplier 43 included in the microwave plasma source 2 is disposed on the top of the transmissive window 112 formed of the second dielectric. With such a configuration, the electromagnetic wave supplier 43 supplies microwaves, which are an example of electromagnetic waves, toward the transmissive window 112.

The periphery of the ceiling plate 111 is covered with a backing member 110 made of a metal such as aluminum, except for the lower surface 111a and a portion supported by the support ring 29. An airtight seal is provided between the support ring 29 and the backing member 110.

As illustrated in FIGS. 1 and 2, the microwave plasma source 2 includes a microwave output part 30 that distributes and outputs microwaves to a plurality of paths, and an antenna module 41 that transmits the microwaves output from the microwave output part 30 to emit the microwaves into the processing container 1.

As illustrated in FIG. 2, the microwave output part 30 includes a microwave power supply 31, a microwave oscillator 32, an amplifier 33 that amplifies the oscillated microwaves, and a distributor 34 that distributes the amplified microwaves to the plurality of paths.

The microwave oscillator 32 oscillates microwaves having a predetermined frequency (for example, 915 MHz) in, for example, a phase locked loop (PLL) manner. The distributor 34 distributes the microwaves amplified by the amplifier 33 while taking impedance matching between the input side and the output side such that a loss of microwaves occurs as little as possible. In addition, the frequency of microwaves may be 700 MHz or more and 3 GHz or less, in addition to 915 MHz.

A plurality of antenna modules 41 are provided to guide the microwaves distributed by the distributor 34 into the processing container 1. Each antenna module 41 includes an amplifier part 42 that mainly amplifies the distributed microwaves, and the electromagnetic wave supplier 43. Further, the electromagnetic wave supplier 43 includes a tuner 60 (see FIG. 1) for impedance matching, and an antenna part 113 that emits the amplified microwaves into the processing container 1. In addition, as illustrated in FIG. 1, the microwaves are emitted from a slit 113S of the antenna part 113 of each electromagnetic wave supplier 43 in the antenna module 41 into the processing container 1 through the transmissive window 112.

The amplifier part 42 includes a phase shifter 46, a variable gain amplifier 47, a main amplifier 48 that configures a solid state amplifier, and an isolator 49. The phase shifter 46 is configured to vary a phase of microwaves and may modulate the characteristics of emission by adjusting the phase of microwaves. For example, under the control of a controller 120, the phase shifter 46 adjusts the phase of microwaves for each antenna module to control directivity and change a distribution of plasma. Further, circularly polarized waves may be obtained by shifting the phase by 90 degrees in adjacent antenna modules. Further, the phase shifter 46 may be used for the purpose of spatial synthesis in the tuner by adjusting the characteristics of delay between components in the amplifier. However, the phase shifter 46 may be omitted when such modulation of the characteristics of emission or such adjustment of the characteristics of delay between components in the amplifier is unnecessary.

The variable gain amplifier 47 is an amplifier for adjusting a change in individual antenna modules or adjusting the intensity of plasma by adjusting a power level of microwaves input to the main amplifier 48. Varying the variable gain amplifier 47 for each antenna module may create a distribution of plasma being generated.

The main amplifier 48 that configures a solid state amplifier may be configured to include, for example, an input matching circuit, a semiconductor amplifying element, an output matching circuit, and a high-Q resonance circuit. The isolator 49 separates reflected microwaves that are reflected by the antenna part 113 and directed toward the main amplifier 48, and includes a circulator and a dummy load (coaxial terminator). The circulator guides the microwaves reflected by the antenna part 113 to the dummy load. The dummy load converts the reflected microwaves guided by the circulator into heat.

Next, returning to FIG. 1, the electromagnetic wave supplier 43 will be described. The electromagnetic wave supplier 43 includes a coaxial-structured waveguide (microwave transmission path) 44 that transmits microwaves, and the antenna part 113 that emits the microwaves transmitted through the waveguide 44 into the processing container 1. Further, the microwaves are emitted from the electromagnetic wave supplier 43 into the processing container 1 through the antenna part 113 and the transmissive window 112, and are synthesized in an internal space of the processing container 1, thereby forming surface wave plasma inside the processing container 1.

The waveguide 44 is configured by coaxially arranging a cylindrical outer conductor 43b and a rod-shaped inner conductor 43a provided at the center of the outer conductor 43b. The antenna part 113 is provided at the tip of the waveguide 44. In the waveguide 44, the inner conductor 43a is on a power supply side and the outer conductor 43b is on a ground side.

Microwave power is supplied to a space between the outer conductor 43b and the inner conductor 43a. Then, the microwave power propagates toward the antenna part 113. Further, the tuner 60 is provided in the waveguide 44. The tuner 60 matches an impedance of load (plasma) inside the processing container 1 with a characteristic impedance of the microwave power supply in the microwave output part 30. Specifically, the tuner 60 achieves impedance matching by vertically moving two slags 61a and 61b between the outer conductor 43b and the inner conductor 43a.

The first dielectric forming the ceiling plate 111 includes a plurality of through-holes. In one example, when the lower surface 111a of the ceiling plate 111 is divided into a central portion, which is a region including the center of the lower surface 111a, and an outer peripheral portion, which is a region around the central portion, as illustrated in FIG. 3, the plurality of through-holes are opened at equal intervals in the lower surface 111a between the transmissive window 112 in the central portion and the transmissive window 112 in the outer peripheral portion.

As illustrated in FIGS. 1 and 3, a plurality of gas supply pipes 114 are fitted respectively into the plurality of through-holes. The gas supply pipe 114 is formed of a dielectric (hereinafter also referred to as “third dielectric”) having a permittivity smaller than the permittivity of the second dielectric of the transmissive window 112. For example, the permittivity of the third dielectric is the same as the permittivity of the first dielectric. The third dielectric is hollow and may be formed of, for example, alumina. The gas supply pipe 114 supplies a gas to the plasma generation space U by flowing the gas through a hollow gas flow path. The plurality of gas supply pipes 114 penetrate the backing member 110 to be connected to a gas supply line 28, and are connected to a gas supplier 27 via the gas supply line 28.

A processing gas is supplied from the gas supplier 27 and is introduced into the processing container 1 from the plurality of gas supply pipes 114 through the gas supply line 28. The introduced processing gas is excited in the plasma generation space U by surface waves of the microwaves introduced into the processing container 1 from the microwave plasma source 2, thereby forming plasma of the processing gas.

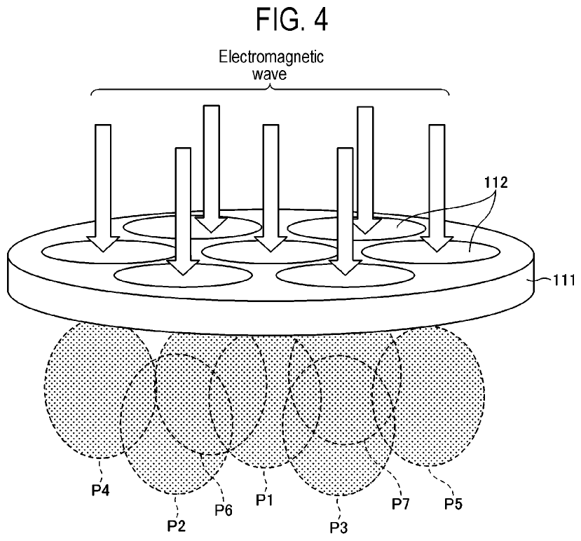

One or a plurality of electromagnetic wave suppliers 43 and transmissive windows 112 are provided in the same number. FIG. 4 is a diagram schematically illustrating an arrangement of the transmissive windows 112 and a local plasma generation according to an embodiment. In the example of FIGS. 3 and 4, the plasma processing apparatus 100 includes seven electromagnetic wave suppliers 43 and seven transmissive windows 112, but the numbers thereof are not limited thereto. Further, the electromagnetic wave suppliers 43 and the transmissive windows 112 are provided in at least one of the central portion or the outer peripheral portion of the ceiling plate 111. In the example of FIGS. 3 and 4, six electromagnetic wave suppliers 43 and six transmissive windows 112 are arranged circumferentially in the outer peripheral portion, and one electromagnetic wave supplier 43 and one transmissive window 112 are arranged in the central portion.

### [Transmissive Window of High Permittivity Material]

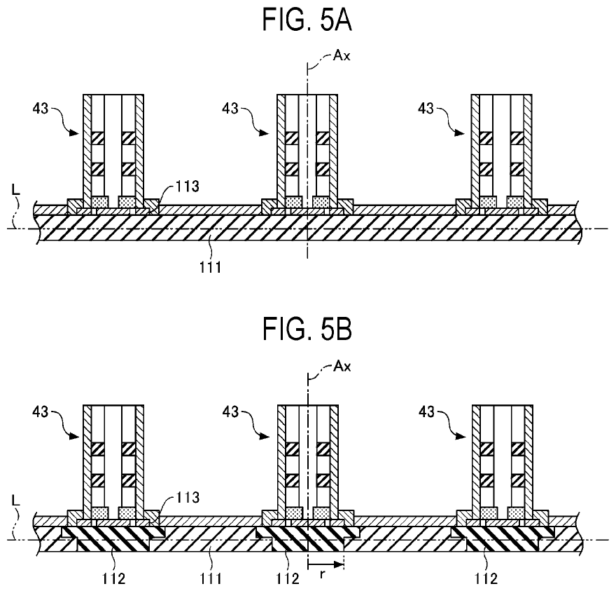

In the related art, a ceiling plate of the plasma processing apparatus 100 is made of a metal such as aluminum and has a structure in which a transmissive window of a dielectric is disposed in an opening of the ceiling plate. In this case, when microwaves propagate through the transmissive window, the microwaves also propagate to a metal surface of the ceiling plate near the transmissive window, so that the electric field becomes stronger especially, for example, at the corners of the metal surface of the ceiling plate, which causes damage to the ceiling plate. This may cause particles or contamination due to the peel-off of a metal. As a way of eliminating the generation of particles and the like, there may be a method of forming the entire surface of the ceiling plate 111 with a dielectric material such as alumina having high plasma resistance. FIG. 5A is an enlarged view of the periphery of the ceiling plate 111 according to a reference example, wherein the entire surface of the ceiling plate 111 is composed of a dielectric material. This may avoid concentration of the electric field on the surface of the ceiling plate, and thus, may reduce particles or contamination, compared to a case where the ceiling plate is made of a metal. In addition, FIG. 5A is a diagram of the reference example used for the purpose of facilitating understanding of the plasma processing apparatus 100 according to the present embodiment, and does not illustrate the related art.

However, in the configuration of the ceiling plate 111 according to the reference example, the electromagnetic field of microwaves transmitted through the dielectric material is diffused radially in the ceiling plate 111, which makes it difficult to locally generate plasma at a desired position as illustrated in FIG. 4. In contrast, in the present embodiment, the transmissive window 112 of a high permittivity material is fitted into the opening of the ceiling plate 111. FIG. 5B is an enlarged view of the periphery of the ceiling plate 111 according to an embodiment. With such a configuration, it is possible to locally generate plasma at a location where the electric field is to be concentrated immediately below the plurality of electromagnetic wave suppliers 43 (antenna modules 41). For example, in the example of FIG. 4, plasma P1 is locally generated below one transmissive window 112 arranged in the central portion, and plasma P2 to P7 is locally generated below six transmissive windows 112 that are arranged circumferentially at equal intervals in the outer peripheral portion. As a result, since the plasma P1 to P7 may be separately adjusted and independently controlled, a distribution ratio of the plasma P1 to P7 may be controlled. Thus, desired plasma may be generated at a desired position in the plasma generation space U as a whole.

Hereinafter, the local plasma generation will be described by taking, as an example, the plasma processing apparatus 100 in which the first dielectric of the ceiling plate 111 is formed of alumina and the second dielectric of the transmissive window 112, on which the electric field of microwaves is to be concentrated, is formed of zirconia as a high permittivity material. However, the materials of the first dielectric and the second dielectric are not limited thereto. Thus, the electromagnetic field of microwaves may be confined in the transmissive window 112 of the high permittivity material by embedding the second dielectric, which is a higher permittivity material than the first dielectric, in the ceiling plate 111. Thus, it is possible to provide the plasma processing apparatus 100 capable of concentrating the electric field of microwaves immediately below the transmissive window 112, thereby locally generating plasma below the transmissive window 112 (see FIG. 4).

### [Simulation Result 1]

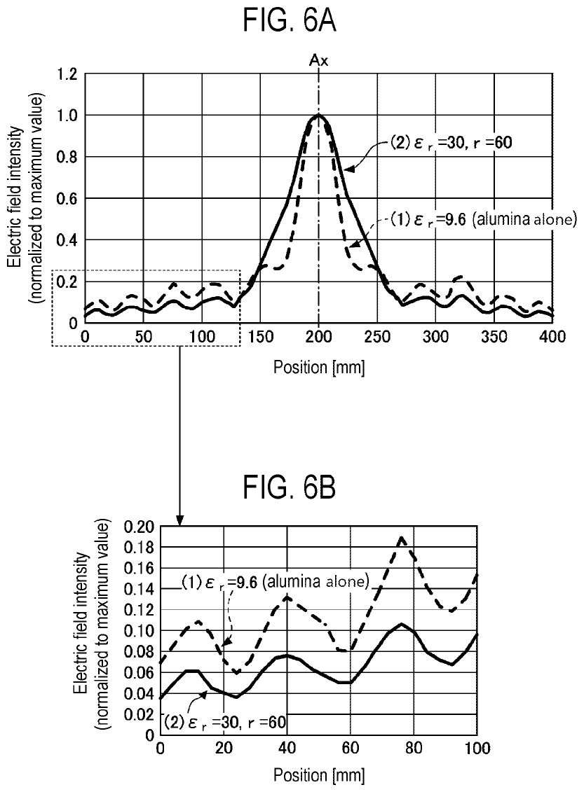

A simulation result for obtaining appropriate values for ranges of the radius r and the permittivity εᵣ of the second dielectric of the transmissive window 112 will be described with reference to FIGS. 6A and 6B. FIGS. 6A and 6B are diagrams illustrating Result 1 obtained by simulating the distribution of electric field intensity in the ceiling plate 111 according to the reference example of FIG. 5A and the embodiment of FIG. 5B. FIG. 6B is an enlarged view of the dotted-line frame in FIG. 6A. (1) illustrated in FIGS. 6A and 6B shows a simulation result of calculating the electric field intensity in the ceiling plate 111 according to the reference example of FIG. 5A. In the reference example, the entire ceiling plate 111 was formed of alumina having a permittivity of about 9.6.

(2) illustrated in FIGS. 6A and 6B shows a simulation result of calculating the electric field intensity in the ceiling plate 111 according to the embodiment of FIG. 5B. In the embodiment, the first dielectric of the ceiling plate 111 was formed of alumina having a permittivity of about 9.6, and the second dielectric of the transmissive window 112 was formed of zirconia having a permittivity of about 30. The radius r of the second dielectric was set to 60 mm. As illustrated in FIG. 5B, the radius r of the second dielectric is a radius of a surface of the transmissive window 112 (second dielectric) exposed to the plasma generation space U. In FIGS. 1 and 5B, the transmissive window 112 has a stepped side surface so that the radius of the top is larger than the radius of the bottom, but the transmissive window 112 may have a cylindrical shape without a stepped portion. As other simulation conditions, the frequency of microwaves supplied was set to 860 MHz.

The horizontal axis in FIGS. 6A and 6B represents a radial position in the ceiling plate 111 when the axis Ax, which passes through the center of the electromagnetic wave supplier 43 (and the transmissive window 112) in the central portion illustrated in FIGS. 5A and 5B, is set to the position of 200 mm from the end portion of the ceiling plate 111 (the center of FIG. 6A). The axis Ax coincides with the central axis of the ceiling plate 111.

The vertical axis in FIGS. 6A and 6B represents the normalized electric field intensity on the line L drawn radially in the ceiling plate 111 illustrated in FIGS. 5A and 5B when the electric field intensity at the position where the axis Ax with the highest electric field intensity and the line L intersect each other is set to “1.” The line L is an imaginary line (straight line) extending in the radial direction of the ceiling plate 111 approximately at the center of the ceiling plate 111 in the thickness direction. However, the line L does not need to be a straight line drawn at approximately half of the thickness of the ceiling plate 111 as long as it is a straight line extending horizontally in the radial direction in the ceiling plate 111.

In the simulation result of FIG. 6A, according to the embodiment in (2), the transmissive window 112 (second dielectric) having a radius r of 60 mm has a diameter of 120 mm and is located within the range of about 140 mm to about 260 mm represented on the horizontal axis in FIG. 6A. Further, within the range of 140 mm to 260 mm represented on the horizontal axis in FIG. 6A, the electric field intensity of the embodiment in (2) is higher than the electric field intensity of the reference example in (1). On the other hand, in FIG. 6B illustrating an enlarged view of the outer edge at one side (in the range of 0 mm to 140 mm) illustrated in FIG. 6A, the electric field intensity of the embodiment in (2) is lower than the electric field intensity of the reference example in (1).

As a result, in the configuration of the ceiling plate 111 according to the present embodiment, the electromagnetic field of microwaves may be confined in the transmissive window 112 by embedding the transmissive window 112, which is formed of the second dielectric of a high permittivity material, in the ceiling plate 111. Thus, it is possible to prevent the electromagnetic field of microwaves supplied from the electromagnetic wave supplier 43 from leaking to the side of the ceiling plate 111 closer to the outer edge than the transmissive window 112.

### [Simulation Result 2]

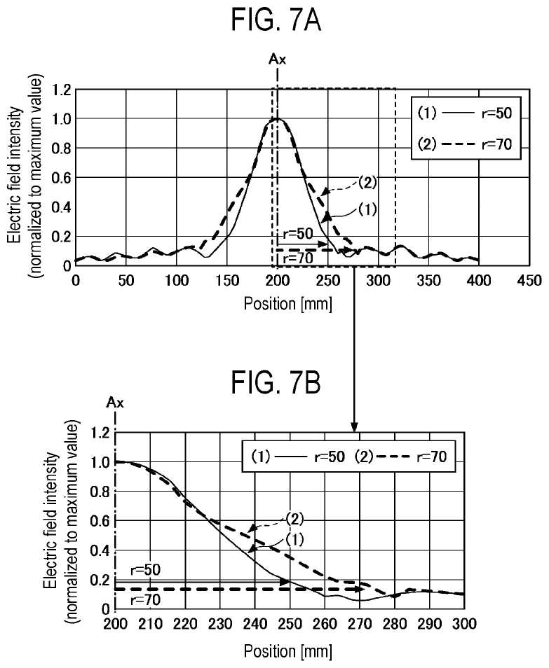

Next, a result of the microwave propagation preventing effect when the radius r of the second dielectric is variably set will be described with reference to FIGS. 7A and 7B. FIGS. 7A and 7B are diagrams illustrating Result 2 obtained by simulating the microwave propagation preventing effect when the radius r of the second dielectric of the transmissive window 112 according to the embodiment is variably set. Other simulation conditions are the same as the simulation conditions for obtaining the result of FIGS. 6A and 6B. FIG. 7B is an enlarged view of the dotted-line frame in FIG. 7A. The horizontal and vertical axes in FIGS. 7A and 7B are the same as the horizontal and vertical axes in FIGS. 6A and 6B. In FIGS. 7A and 7B, (1) shows the electric field intensity on the line L (see FIG. 5B) when the radius r of the second dielectric of the transmissive window 112 is 50 mm, and (2) shows the electric field intensity on the line L (see FIG. 5B) when the radius r of the second dielectric is 70 mm.

According to this, it can be seen that the distribution of electric field changes depending on the radius r of the second dielectric of the transmissive window 112. However, in both cases where the radius r is 50 mm and 70 mm, the electric field is highly distributed in the second dielectric but is remarkably less at the outer edge by embedding the transmissive window 112 of the second dielectric in the ceiling plate 111. That is, it was possible to confine the electromagnetic field of microwaves in the second dielectric. For example, when the radius r of the second dielectric is 50 mm, the electric field intensity in the second dielectric having a diameter of 100 mm was high (in the range of 150 mm to 250 mm), and it was possible to reduce the electric field intensity in the first dielectric at the outer edge beyond 250 mm. Similarly, when the radius r of the second dielectric is 70 mm, the electric field intensity in the second dielectric having a diameter of 140 mm was high (in the range of 130 mm to 270 mm), and it was possible to reduce the electric field intensity in the first dielectric at the outer edge beyond 270 mm.

In this way, the electromagnetic field of microwaves supplied from the electromagnetic wave supplier 43 may be prevented from leaking to the side of the ceiling plate 111 of the first dielectric closer to the outer edge than the transmissive window 112. As will be understood from the above description, when a plurality of transmissive windows 112 are arranged in the ceiling plate 111, there is no influence of microwaves transmitted through adjacent transmissive windows 112 since electromagnetic waves may be confined in the high permittivity material of each transmissive window 112. Thus, the adjacent transmissive windows 112 need not be in contact with each other by interposing the first dielectric therebetween, and the thickness of the first dielectric provided between the adjacent transmissive windows 112 does not matter. That is, when the plurality of transmissive windows 112 are provided in the openings 111b of the ceiling plate 111, the thickness of the first dielectric of the ceiling plate 111 between the plurality of transmissive windows 112 may be a thin film.

### [Simulation Result 3]

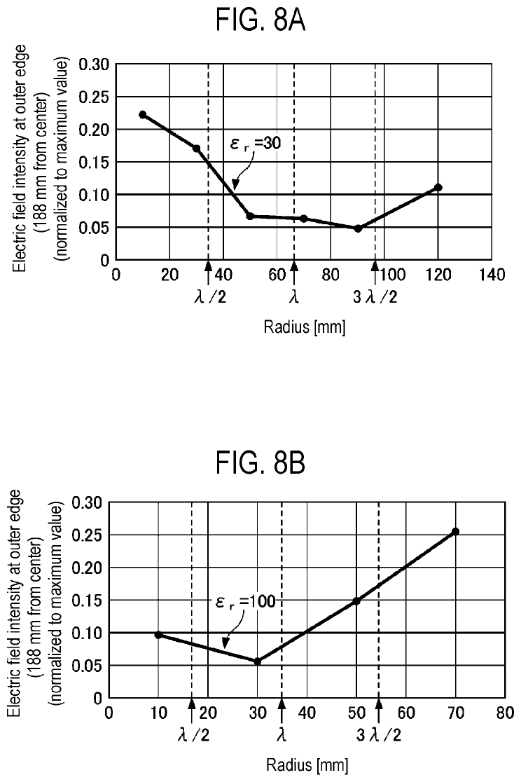

Next, a simulation result for obtaining an appropriate value of the radius r of the second dielectric will be described with reference to FIGS. 8A and 8B. The horizontal axis in FIG. 8A represents the radius r of the second dielectric when the second dielectric of the transmissive window 112 is formed of zirconia having a permittivity εᵣ of 30. The vertical axis in FIG. 8A represents the normalized electric field intensity at the outer edge of 188 mm from the center (12 mm from the end of the ceiling plate 111) when the axis Ax is set to the center position (200 mm) of the ceiling plate 111 and the electric field intensity at the position of the axis Ax is set to “1.” The simulation conditions used in FIGS. 8A and 8B are different from those in FIGS. 6A and 6B only in that the material of the second dielectric is changed, and other simulation conditions are the same as the simulation conditions for obtaining the result of FIGS. 6A and 6B.

λ indicated on the horizontal axis in FIG. 8A is the effective wavelength of microwaves in the second dielectric of the transmissive window 112. When the second dielectric is formed of zirconia having a permittivity εᵣ of 30, the effective wavelength λ of microwaves in the second dielectric is 63.7 mm. According to the simulation result of FIG. 8A, it is preferable that the radius r of the second dielectric formed of zirconia is within the range of λ/2≤r≤3λ/2. Thus, it is possible to sufficiently prevent the electromagnetic field of microwaves from being diffused from the second dielectric of the transmissive window 112 to the first dielectric of the outer edge, and thus, to sufficiently reduce the electric field intensity at the outer edge.

FIG. 8B illustrates a relationship between the radius r of the second dielectric and the normalized electric field intensity when the second dielectric is formed of titanium oxide having a permittivity εᵣ of 100. In FIG. 8B, the horizontal axis represents the radius r of the second dielectric formed of titanium oxide, and the vertical axis represents the normalized electric field intensity at the outer edge of 188 mm from the center when the electric field intensity of the axis Ax at the center position is set to “1.”

The higher the permittivity εᵣ, the shorter the effective wavelength λ of microwaves propagated in the second dielectric. In the case of the titanium oxide, the effective wavelength λ of microwaves in the second dielectric was 34.9 mm. According to the simulation result of FIG. 8B, it is preferable that the radius r of the second dielectric formed of the titanium oxide is also within the range of λ/2≤r≤3λ/2. Thus, it is possible to sufficiently prevent the electromagnetic field of microwaves from being diffused from the second dielectric of the transmissive window 112 to the first dielectric of the outer edge, and thus, to sufficiently reduce the electric field intensity at the outer edge.

As will be understood from the above description, when the radius r of the second dielectric satisfies the condition of λ/2≤r≤3λ/2 based on the simulation result of FIGS. 8A and 8B, it is possible to prevent the electromagnetic field of microwaves from being diffused from the second dielectric of the transmissive window 112 to the first dielectric of the outer edge. Thus, it is possible to locally generate plasma by increasing the electric field intensity below the transmissive window 112.

### [Simulation Result 4]

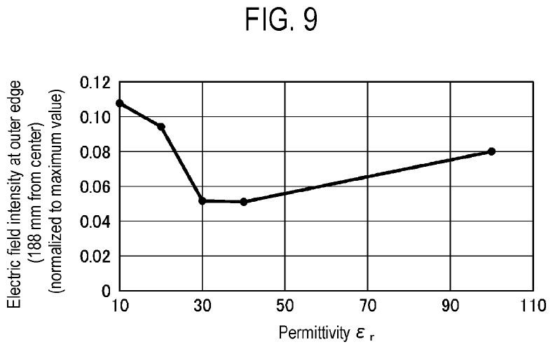

FIG. 9 illustrates an example of the permittivity εᵣ of the second dielectric constituting the transmissive window 112 and the electric field intensity at the outer edge of 188 mm from the position of the axis Ax according to an embodiment. The horizontal axis in FIG. 9 represents the permittivity εᵣ of the second dielectric of the transmissive window 112, and the vertical axis in FIG. 9 represents the normalized electric field intensity at the outer edge of 188 mm from the center when the electric field intensity of the axis Ax at the center position (200 mm) of the ceiling plate 111 is set to “1.” The simulation conditions used in FIG. 9 are different from those in FIGS. 8A and 8B only in that the permittivity of the second dielectric is changed, and other simulation conditions are the same as the simulation conditions for obtaining the result of FIGS. 8A and 8B.

According to this, when the permittivity εᵣ of the second dielectric constituting the transmissive window 112 is 30 or more, the electromagnetic field of microwaves may be further confined in the transmissive window 112, compared to when the permittivity εᵣ of the second dielectric is 20. Thus, it is possible to prevent the electromagnetic field from being diffused to the outer edge outside the transmissive window 112, and thus, to locally generate plasma below the transmissive window 112 by concentrating the electric field below the transmissive window 112.

Accordingly, from the simulation result of FIG. 9, for the first dielectric formed of alumina having a permittivity of 9.6, the permittivity εᵣ of the second dielectric of the transmissive window 112 may be at least 3 times the permittivity of the first dielectric of the ceiling plate 111. Specifically, when the permittivity εᵣ of the second dielectric of the transmissive window 112 is 3 times or more and 10 times or less than the permittivity of the first dielectric of the ceiling plate 111, it is possible to prevent the electromagnetic field of microwaves from being diffused to the outer edge outside the transmissive window 112.

The second dielectric of the transmissive window 112 may be a high permittivity material having a permittivity of 30 or more and 100 or less. Thus, the second dielectric of the transmissive window 112 may be zirconia having a permittivity of 30, or titanium oxide having a permittivity of 100. Sapphire may be used for the second dielectric of the transmissive window 112 depending on the first dielectric.

Furthermore, specifically, the permittivity εᵣ of the second dielectric of the transmissive window 112 may be 3 times or more and 4 times or less than the permittivity of the first dielectric of the ceiling plate 111 since this range may further sufficiently prevent the electromagnetic field from being diffused to the outer edge outside the transmissive window 112. Thus, the transmissive window 112 may be formed of zirconia having a permittivity of 30 to 40.

As described above, according to the plasma processing apparatus 100 of the present embodiment, the transmissive window 112 made of a high permittivity material is provided at a location where the electric field is to be concentrated in the ceiling plate 111 constituting the ceiling wall of the processing container 1. That is, the second dielectric of the transmissive window 112 is formed of a high permittivity material having a higher permittivity than the permittivity of the first dielectric of the ceiling plate 111. Thus, it is possible to confine the electric field of microwaves in the transmissive window 112, and thus, to prevent the propagation of microwaves outward of the transmissive window 112. Accordingly, it is possible to reduce the electric field intensity at the outer edge outside the transmissive window 112.

According to the present disclosure in some embodiments, it is possible to prevent electromagnetic waves from propagating inside a ceiling plate that constitutes a ceiling wall of a processing container included in a plasma processing apparatus.

The plasma processing apparatus according to the embodiments disclosed herein should be considered to be exemplary and not limitative in all respects. The embodiments may be modified and improved in various forms without departing from the scope of the appended claims and gist thereof. The matters described in the above multiple embodiments may have other configurations to the extent that they are not contradictory, and may be combined to the extent that they are not contradictory.

The plasma processing apparatus of the present disclosure may be applied to a radial line slot antenna apparatus.

What is claimed is:

1. A plasma processing apparatus comprising:
a processing container;
a ceiling plate that constitutes a ceiling wall of the processing container, is formed of a first dielectric, and has an opening formed in the first dielectric;
at least one transmissive window disposed in the opening and formed of a second dielectric having a second permittivity greater than a first permittivity of the first dielectric; and
at least one electromagnetic wave supplier configured to supply electromagnetic waves toward the at least one transmissive window.

2. The plasma processing apparatus of claim 1, wherein the processing container and the ceiling plate define a plasma generation space, and
wherein a surface of the second dielectric exposed to the plasma generation space is flush with a surface of the first dielectric that is adjacent to the second dielectric and is exposed to the plasma generation space.

3. The plasma processing apparatus of claim 1, wherein the at least one electromagnetic wave supplier includes a plurality of electromagnetic wave suppliers, the at least one transmissive window includes a plurality of transmissive windows, and the number of the plurality of electromagnetic wave suppliers and the number of the plurality of transmissive windows are identical to each other.

4. The plasma processing apparatus of claim 3, wherein the at least one electromagnetic wave supplier and the at least one transmissive window are provided in at least one of a central portion or an outer peripheral portion of the ceiling plate.

5. The plasma processing apparatus of claim 1, wherein an effective wavelength of the electromagnetic waves in the second dielectric is λ, and the at least one transmissive window is configured such that a radius r of a surface of the second dielectric exposed to a plasma generation space falls within a range of λ/2≤r≤3λ/2.

6. The plasma processing apparatus of claim 1, wherein the second permittivity of the second dielectric is 3 times or more than the first permittivity of the first dielectric.

7. The plasma processing apparatus of claim 6, wherein the second permittivity of the second dielectric is 3 times or more and 10 times or less than the first permittivity of the first dielectric.

8. The plasma processing apparatus of claim 7, wherein the second permittivity of the second dielectric is 3 times or more and 4 times or less than the first permittivity of the first dielectric.

9. The plasma processing apparatus of claim 1, wherein the at least one transmissive window includes a plurality of transmissive windows, and
wherein a thickness of the first dielectric interposed between a plurality of second dielectrics forming the plurality of transmissive windows is a thin film.

10. The plasma processing apparatus of claim 1, wherein the second dielectric is a high permittivity material having the second permittivity of 30 or more and 100 or less.

11. The plasma processing apparatus of claim 1, wherein the first dielectric has a plurality of through-holes,
wherein the plasma processing apparatus comprises a plurality of gas supply pipes disposed respectively in the plurality of through-holes, and
wherein each of the plurality of gas supply pipes is formed of a hollow third dielectric having a third permittivity smaller than the second permittivity of the second dielectric and is configured to flow a gas through the third dielectric.
